(19) United States
(12) Patent Application Publication
(10) Pub. No.: US 2023/0230867 A1
(43) Pub. Date: Jul. 20, 2023

(54) PRE-ALIGNER

(71) Applicant: Ming-Sheng Chen, New Taipei City (TW)

(72) Inventor: Ming-Sheng Chen, New Taipei City (TW)

(73) Assignee: STEK CO., LTD., New Taipei City (TW)

(21) Appl. No.: 18/154,104

(22) Filed: Jan. 13, 2023

(30) Foreign Application Priority Data
Jan. 18, 2022 (TW) 111101958

(51) Int. Cl. H01L 21/68; H01L 21/67; H01L 21/683; H01L 21/687

(52) U.S. Cl. CPC H01L 21/68; H01L 21/67259; H01L 21/6833; H01L 21/68764

(57) ABSTRACT

A pre-aligner includes a base, a rotating unit, a platform and a sensing unit. The rotating unit includes a motor and an axle. The motor is inserted in the base. The axle is rotated by the motor. The platform is coaxially connected to the axle and includes electrodes for generating an electrostatic field for attracting the substrate. The sensing unit includes a box and a sensor. The box is located on the base. The sensor is movable in the box to sense the orienting portion of the substrate.

### BACKGROUND OF INVENTION

### 1. Field of Invention

The present invention relates to a substrate and, more particularly, to a pre-aligner for a substrate.

### 2. Related Prior Art

When a substrate such as a semiconductor wafer and a filtering glass panel undergoes a process such as inspection, imaging, printing, laser irradiation and cutting, the substrate will suffer grave and irreparable defects if there is any misalignment. Hence, the substrate must be aligned before it is subjected to such process. To facilitate the pre-alignment, the substrate is formed with an orienting portion such as a notch or a flat in a substantially circular edge of the substrate. A pre-aligner senses the orienting portion to align the substrate. The pre-aligner can be a stand-alone device or a part of a larger machine.

The substrate is often a composite substrate made of various types of metal that exhibit different values of ductility. Hence, the substrate often suffers warpage after grinding and polishing when its thickness is smaller than 200 μm, 100 μm or even 50 μm and its diameter is larger than 8, 12 or even more inches.

Referring to FIG. 1, a substrate 100 is laid on a platform 200 and moved. The platform 200 includes orifices 201 for sucking the substrate 100. When suffering grave warpage, the substrate 100 cannot properly cover the orifices 201. Hence, the orifices 201 cannot properly suck the substrate 100. Misalignment could occur due to such improper suction. In the worst scenario, the substrate 100 is tossed from the platform 200 during rotation of the platform 200. Moreover, should the suction be excessively intense, the substrate 100 could suffer cracks that affect the quality and yield of the substrate 100.

The present invention is therefore intended to obviate or at least alleviate the problems encountered in the prior art.

### SUMMARY OF INVENTION

It is an objective of the present invention to provide a pre-aligner for firmly holding a substrate.

It is another objective of the present invention to provide a pre-aligner for firmly holding a substrate without any risk of damaging the substrate.

It is another objective of the present invention to provide a pre-aligner for flattening a substrate for effective pre-alignment.

To achieve the foregoing objectives, the pre-aligner includes a base, a rotating unit, a platform and a sensing unit. The rotating unit includes a motor and an axle. The motor is inserted in the base. The axle is rotated by the motor. The platform is coaxially connected to the axle and includes electrodes for generating an electrostatic field for attracting the substrate. The sensing unit includes a box and a sensor. The box is located on the base. The sensor is movable in the box to sense the orienting portion of the substrate.

Other objectives, advantages and features of the present invention will be apparent from the following description referring to the attached drawings.

### BRIEF DESCRIPTION OF DRAWINGS

The present invention will be described via detailed illustration of two embodiments referring to the drawings wherein:

FIG. 1 is a side view of a side view of a portion of a conventional pre-aligner vacuum sucking a substrate;

FIG. 2A is a top view of a substrate with a notch in a substantially circular edge for alignment;

FIG. 2B is a top view of a substrate with a flat in a substantially circular edge for alignment;

FIG. 3 is a perspective view of a pre-aligner according to the first embodiment of the present invention;

FIG. 4 is a cross-sectional view of the pre-aligner shown in FIG. 3;

FIG. 5 is a top view of a platform of a pre-aligner according to the second embodiment of the present invention;

FIG. 6 is a flow chart of a method for operating the pre-aligner shown in FIG. 3;

FIG. 7 is a cross-sectional view of the pre-aligner shown in FIG. 3;

FIG. 8A is a cross-sectional view of a portion of the pre-aligner shown in FIG. 3;

FIG. 8B is a cross-sectional view of the portion of the pre-aligner in another position than shown in FIG. 8A;

FIG. 9 is a cross-sectional view of the pre-aligner in another position than shown in FIG. 7; and

FIG. 10 is a cross-sectional view of the pre-aligner in another position than shown in FIG. 9.

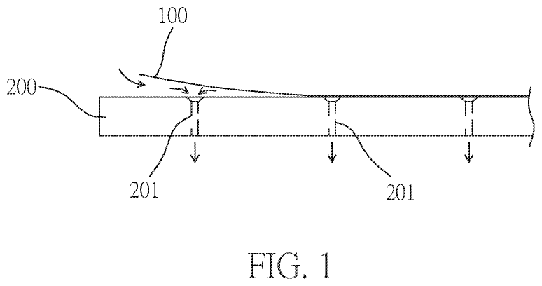

### DETAILED DESCRIPTION OF EMBODIMENTS

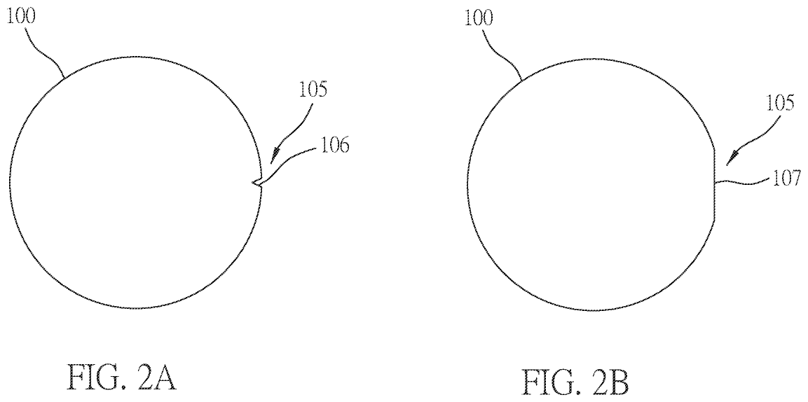

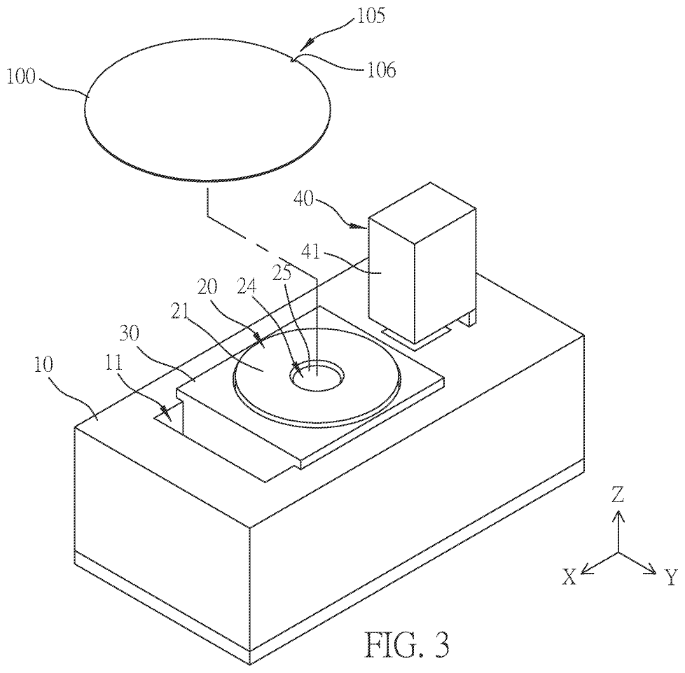

Referring to FIG. 3, a pre-aligner includes a base 10, a platform 20, a moving mechanism 30 and a sensing unit 40 according to a first embodiment of the present invention. As a stand-alone device or a part of a larger machine, the pre-aligner aligns a substrate 100 shown in FIG. 2A or 2B. The substrate 100 is formed with an orienting portion 105 that includes a notch 106 (FIG. 2A) or a flat 107 (FIG. 2B) at a substantially circular edge.

The base 10 is a hollow element formed with an opening 11 in an upper face. The moving mechanism 30 is inserted in the base 10 via the opening 11. The moving mechanism 30 moves the platform 20 relative to the sensing unit 40, which is supported on the base 10.

The platform 20 includes a fetching face 21 at an upper end. The fetching face 21 is used to contact the substrate 100. Electrodes 22 are arranged on the fetching face 21. The electrodes 22 are electrically connected to an electrostatic generator (not shown). The electrodes 22 enable the fetching face 21 to attract the substrate 100 electrostatically, thereby keeping the substrate 100 in position relative to the fetching face 21. A diameter of the platform 20 is smaller than a diameter of the substrate 100 and is larger than one third of the diameter of the substrate 100. The platform 20 does not reach the orienting portion 105 of the substrate 100 as the substrate 100 rests coaxially on the platform 20. However, the platform 20 adequately attracts and flattens the entire substrate 100, including the orienting portion 105.

The moving mechanism 30 includes a rotating unit, a lifting unit and a translating unit 35. The rotating unit rotates the platform 20. The lifting unit is coaxial with the platform 20. Moreover, the lifting unit is movable up and down relative to the platform 20. The translating unit 35 translates the moving mechanism 30, the platform 20 and the substrate 100 relative to the base 10 and the sensing unit 40.

The rotating unit includes a motor 31 and an axle 32. The motor 31 is carried on the translating unit 35. The axle 32 is coaxially connected to the platform 20. A first pulley (not numbered) is coaxially connected to the motor 31. A second pulley (not numbered) is coaxially connected to the axle 32. A belt (not numbered) is wound on the first and second pulleys. Thus, the motor 31 rotates the platform 20 via the axle 32, the first and second pulleys and the belt. A slip ring can be used to keep the electrodes 22 electrically connected to the electrostatic generator in the rotation of the platform 20.

The lifting unit includes a support 24 and a pneumatic cylinder 33 that includes a piston rod 34. The pneumatic cylinder 33 can be replaced with a hydraulic cylinder in another embodiment.

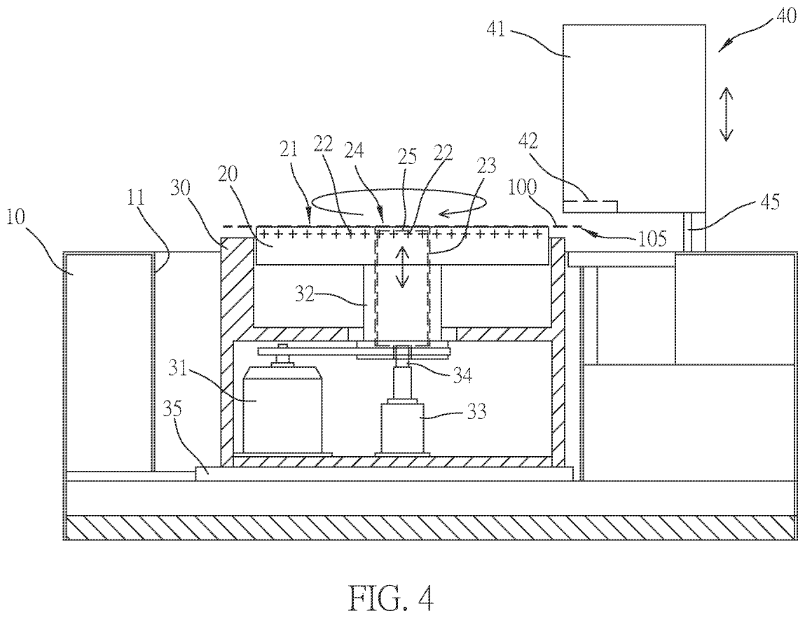

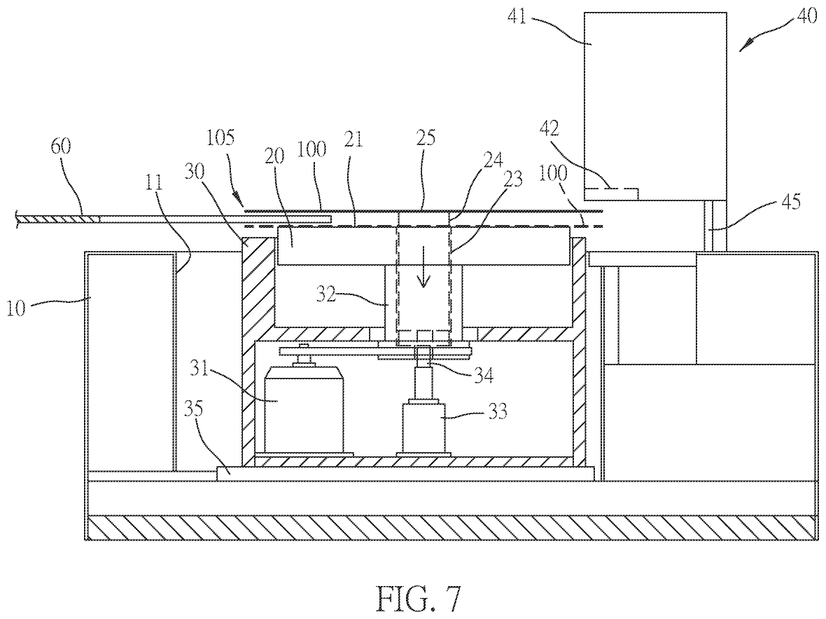

The support 24 preferably includes a single rod coaxially inserted in the axle 32, which is a hollow element. The support 24 can include three rods in another embodiment. The support 24 includes a fetching face 25 at an upper end. Electrodes 22 (FIG. 4) are arranged on the fetching face 25. The electrodes 22 enable the fetching face 25 to attract the substrate 100 electrostatically. The support 24 is extensible through an aperture 23 centrally made in the platform 20 so that the fetching face 25 is movable between a lower position and an upper position. In the lower position, the fetching face 25 is coplanar with or lower than the fetching face 21 (FIG. 4). In the upper position, the fetching face 25 is higher than the fetching face 21 (FIG. 7).

The pneumatic cylinder 33 is carried on the translating unit 35. The piston rod 34 includes an end connected to the support 24 and another end movable in the pneumatic cylinder 33. Thus, the pneumatic rod 33 lifts or lowers the support 24 relative to the platform 20 without interfering with the rotation of the platform 20.

The translating unit 35 is supported on the base 10. The translating unit 35 can include a motor, tracks and threaded rods. Thus, the translating unit 35 can move the platform 20 and the substrate 100 along an X-axis, a Y-axis and a Z-axis relative to the sensing unit 40.

The sensing unit 40 senses the substrate 100. The sensing unit 40 can be an optical, imagery or mechanical sensing unit. The sensing unit 40 includes a box 41, a sensor 42 and an elevator 45. The box 41 is located on the base 10, next to the platform 20. The elevator 45 is used to move the sensor 42 in the box 41. The sensor 42 is used to sense the orienting portion 105 of the substrate 100 to align the substrate 100. The elevator 45 can include a motor, tracks and a threaded rod.

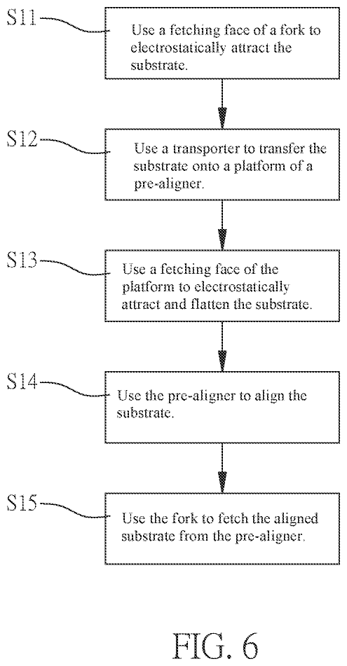

To align a substrate 100, the pre-aligner executes a process to be described referring to FIG. 6.

At S11, the substrate 100 is provided with an orienting portion 105 at a substantially circular edge.

At S12, the substrate 100 is moved into the pre-aligner. To this end, a transporter in the form of a robot with a fork 60 (FIG. 7) or any other end effector is used. In the beginning, the cylinder 33 moves the support 24 to the upper position. Then, the fork 60 moves the substrate 100 to a position above the support 24. Then, the fork 60 descends, thereby transferring the substrate 100 onto the support 24. Then, the fetching face 25 attracts the substrate 100 electrostatically. Then, the fork 60 leaves the pre-aligner. Then, the pneumatic cylinder 33 moves the support 24 to the lower position, thereby laying the substrate 100 onto the platform 20.

In another embodiment, while moving to the upper position, the support 24 moves beyond the fork 60. Thus, support 24 takes the substrate 100 from the fork 60 without having to lower the fork 60.

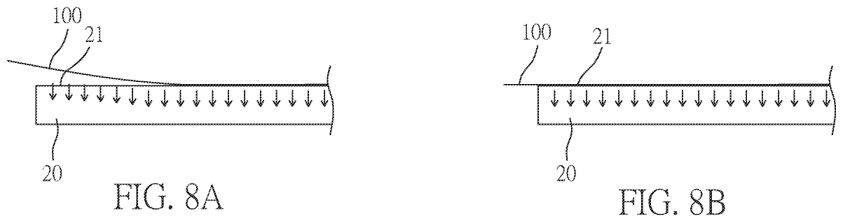

At S13, the platform 20 electrostatically attracts the substrate 100. To this end, the electrodes 22 generate an electrostatic field on the fetching face 21. Moreover, the fetching face 21 flattens the substrate 100 (FIG. 8B) even if the substrate 100 originally suffers grave warpage (FIG. 8A). Hence, even the portion of the substrate 100 that extends beyond the fetching face 21 is coplanar with the other portion of the substrate 100.

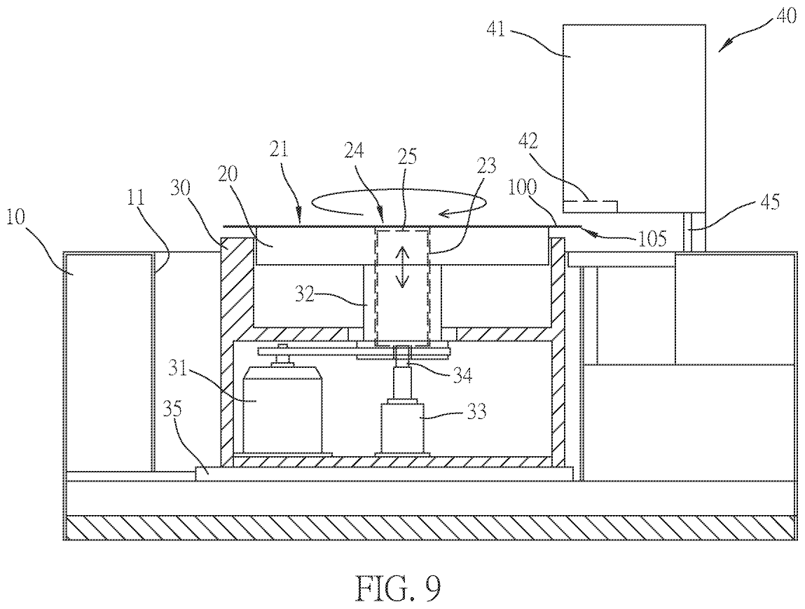

At S14, the substrate 100 is rotated to allow the sensing unit 40 to sense the orienting portion 105. Referring to FIG. 9, after the fetching face 21 of the platform 20 properly sucks the substrate 100, the moving mechanism 30 moves the platform 20 so that the substantially circular edge of the substrate 100 is located below the sensor 42. The sensor 42 is lifted or lowered to properly sense the substantially circular edge of the substrate 100. The motor 31 rotates the platform 20 so that the orienting portion 105 of the substrate 100 is located below the sensor 42 to allow the sensor 42 to properly sense the orienting portion 105 of the substrate 100. Thus, the substrate 100 is aligned.

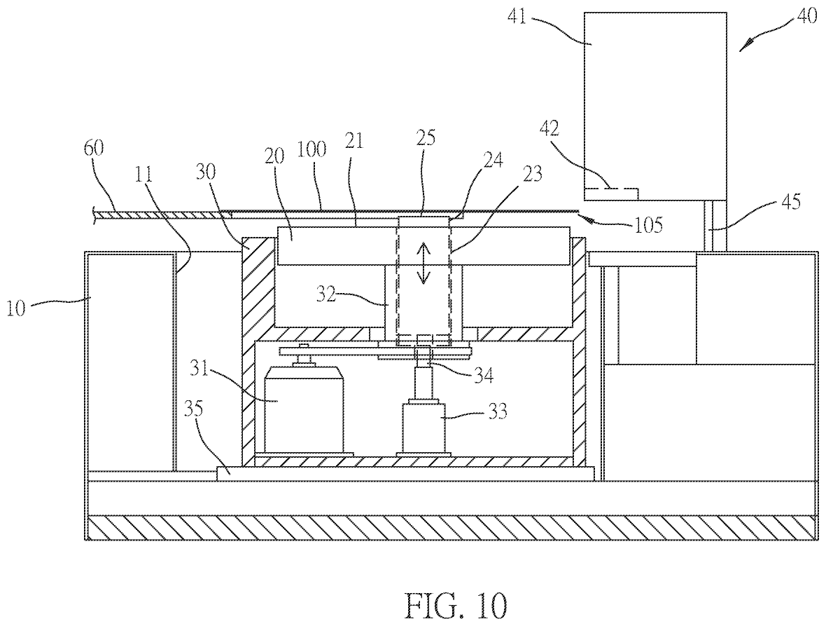

At S15, the substrate 100 is moved from the pre-aligner. Referring to FIG. 10, the support 24 is moved to the upper position and the fetching face 25 sucks the substrate 100 electrostatically. The fork 60 is moved to the position below the substrate 100. The fork 60 is lifted to bear the substrate 100. Then, the substrate 60 moves the substrate 100 from the pre-aligner.

In another embodiment, instead of the lifting of the fork 60, the support 24 is moved to the lower position to transfer the substrate 100 to the fork 60.

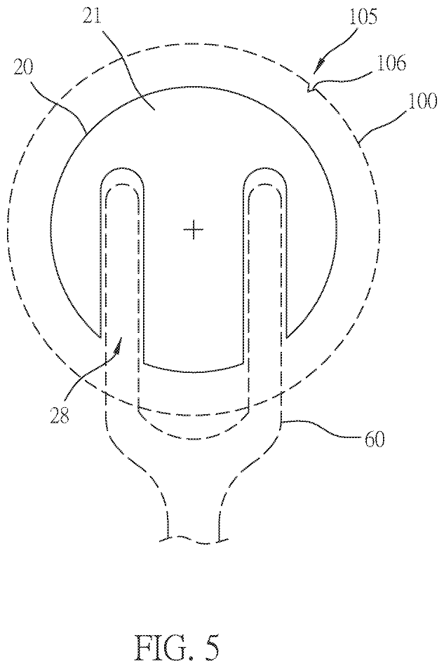

Referring to FIG. 5, there is shown a pre-aligner according to a second embodiment of the present invention. The second embodiment is like the first embodiment except for two things. Firstly, the support 24 and the pneumatic cylinder 33 are omitted. Secondly, the platform 20 includes two slits 28. The slits 28 are located and shaped corresponding to two prongs of the fork 60 of the robot.

To transfer the substrate 100 onto the platform 20 from the fork 60, the fork 60 is moved to a position above the platform 20. Now, the substrate 100 is located above the platform 20. Then, the fork 60 is lowered to a position below the platform 20 as the prongs of the fork 60 are inserted in the slits 28. Thus, the substrate 100 is transferred onto the platform 20 from the fork 60. Then, the fork 60 is moved from the pre-aligner, i.e., the prongs of fork 60 are moved from the slits 28.

The foregoing process is reversed to transfer the substrate 100 to the fork 60 from the platform 20. Then, the substrate 100 can undergo other tasks.

The electrodes 22 are used on the fetching faces 21 and 25 to generate electrostatic fields to attract the substrate 100. Hence, the fetching faces 21 and 25 properly attract the substrate 100 even if the substrate 100 suffers grave warpage. Furthermore, the fetching face 21 flattens the substrate 100 to allow effective alignment of the substrate 100. Moreover, there is substantially no risk of damaging the substrate 100 during the transfer and alignment of the substrate 100.

The present invention has been described via the illustration of the embodiments. Those skilled in the art can derive variations from the embodiments without departing from the scope of the present invention. Therefore, the embodiments shall not limit the scope of the present invention defined in the claims.

1. A pre-aligner for a substrate formed with an orienting portion, the pre-aligner comprising:
a base;
a rotating unit comprising a motor inserted in the base and an axle rotated by the motor;
a platform coaxially connected to the axle and comprising a fetching face formed with electrodes for generating an electrostatic field to attract the substrate; and
a sensing unit comprising a box located on the base and a sensor movable in the box to sense the orienting portion of the substrate.

2. The pre-aligner according to claim 1, wherein the platform does not reach the orienting portion of the substrate, and a diameter of the platform is larger than one third of a diameter of the substrate to allow the platform to render the entire substrate flat.

3. The pre-aligner according to claim 1, further comprising a support movable between a lower position coplanar with or lower than the platform and an upper position higher than the platform, wherein the platform carries the substrate when the support is in the upper position, and the support carries the substrate when the support is in the upper position.

4. The pre-aligner according to claim 3, further comprising a cylinder inserted in the base and formed with a piston rod connected to the support.

5. The pre-aligner according to claim 3, wherein the support comprises a fetching face formed with electrodes.

6. The pre-aligner according to claim 1, wherein the platform comprises two slits corresponding to two prongs of a fork for bringing the substrate into and from the pre-aligner.

7. The pre-aligner according to claim 1, further comprising a translating unit for moving the rotating unit relative to the sensing unit along an X-axis, a Y-axis and a Z-axis.

8. A method for operating a pre-aligner comprising the steps of:
providing a substrate with an orienting portion;
moving the substrate into the pre-aligner;
generating an electrostatic field on the pre-aligner to attract the substrate;
rotating the substrate to allow the orienting portion of the substrate to be sensed by the pre-aligner; and
moving the substrate from the pre-aligner.
